(19) United States
(12) Patent Application Publication
(10) Pub. No.: US 2003/0227763 A1
(43) Pub. Date: Dec. 11, 2003

(54) Apparatus for seating a SIM card

(76) Inventors: Hsiang-Lung Kao, Taipei (TW); Kuo-Hsiang Wu, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/280,966

(22) Filed: Oct. 25, 2002

(30) Foreign Application Priority Data
Jun. 11, 2002 (TW) 91208686

(51) Int. Cl. H05K 9/00

(52) U.S. Cl. 361/818

(57) ABSTRACT

An apparatus for seating a SIM card. The apparatus is embedded in the case of a cell phone, and includes a first plate and a second plate. The first plate includes a pair of shafts and defines a pair of parallel grooves for receiving the SIM card. The second plate includes a depressed portion to contain the first plate, wherein the depressed portion defines a pair of holes and a pair of channels connecting the pair of holes, and the pair of shafts of the first plate are slidably disposed in the pair of channels.

### FIELD OF THE INVENTION

The present invention relates to an apparatus for seating a SIM (Subscriber Identification Module) card, and in particular to an apparatus to protect and fix the SIM card therein.

### DESCRIPTION OF THE RELATED ART

FIG. 1 shows a conventional SIM card-seating apparatus. A depressed portion is disposed on the back of a cell phone to contain a SIM card 10. A connector (not shown) is embedded in the depressed portion to contact the SIM card 10. A plate 11 is disposed to cover a portion of the depressed portion, and is slidable in the direction shown in FIG. 1 so that the SIM card 10 is fixed in the depressed portion. Furthermore, a pair of grooves is disposed on sides of the plate 11 to limit the sliding direction of plate 11.

Conventionally, the SIM card 10 is easily abraded because of the plate 11 sliding, thereby compromising the apparatus' function.

FIG. 2 shows another conventional SIM card-seating apparatus. A depressed portion 22 is disposed on the back of a cell phone to contain a SIM card 10, wherein a pair of grooves 21 are defined on the sides of the depressed portion 22. The grooves are utilized to receive insertion of the SIM card in the direction shown in FIG. 2. A connector (not shown) is embedded in the depressed portion to contact the SIM card 10.

As shown in FIG. 2, the conventional apparatus lacks a fixture member to effectively constrain the SIM card 10 from sliding in the depressed portion and to solidly connect the SIM card and connector.

FIG. 3 shows another conventional SIM card-seating apparatus. In this case, a fixture cover 13 is disposed above the connector 23 to solidly connect the SIM card and connector. However, this structure makes it inconvenient to replace SIM cards. In addition, the fixture cover 13 will loosen after frequent SIM card replacement.

Hence, there is a need for a better apparatus for seating a SIM card.

### SUMMARY OF THE INVENTION

Accordingly, an object of the present invention is to provide an apparatus for seating a SIM card, wherein the apparatus is embedded in a case of a cell phone and includes a first plate and a second plate. The first plate includes a pair of shafts and defines a pair of parallel grooves for receiving the SIM card. The second plate includes a depressed portion to contain the first plate, wherein the depressed portion defines a pair of holes and a pair of channels connecting the pair of holes, the shafts of the first plate slidably disposed in the channels.

The first plate is slidably connected to the second plate so that the first plate moves between a first position and a second position, wherein the first plate is rotatable with respect to the second plate in the first position, and is engaged with the second plate in the second position.

The present invention has the following advantages: the first plate embedded in the depressed portion allows the height of the apparatus to be reduced, the SIM card enters the grooves without abrading, a portion of the apparatus is covered by the case of the cell phone so that the SIM card can be fixed more easily, the apparatus is fabricated independent from the connector, reducing costs, and finally has the advantage of electromagnetic interference shielding material.

A detailed description is given in the following embodiments with reference to the accompanying drawings.

### BRIEF DESCRIPTION OF THE DRAWING

FIG. 1 is a schematic view showing a first conventional SIM card-seating apparatus;

FIG. 2 is a schematic view showing a second conventional SIM card-seating apparatus;

FIG. 3 is a schematic view showing a third conventional SIM card-seating apparatus;

FIG. 4A is a schematic view of the apparatus of the present invention;

FIG. 4B shows part of the apparatus of the invention;

FIG. 5 shows the apparatus of the present invention disposed on a printed circuit board;

FIG. 6 shows the apparatus of the present invention embedded in the case of a call phone;

FIG. 7 shows the first plate in the first position;

FIG. 8 shows the first plate in the second position.

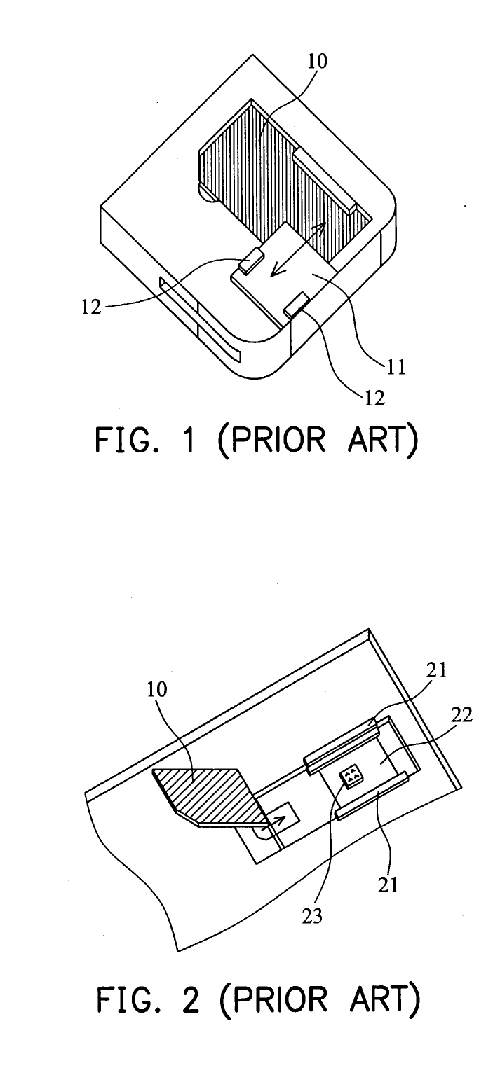

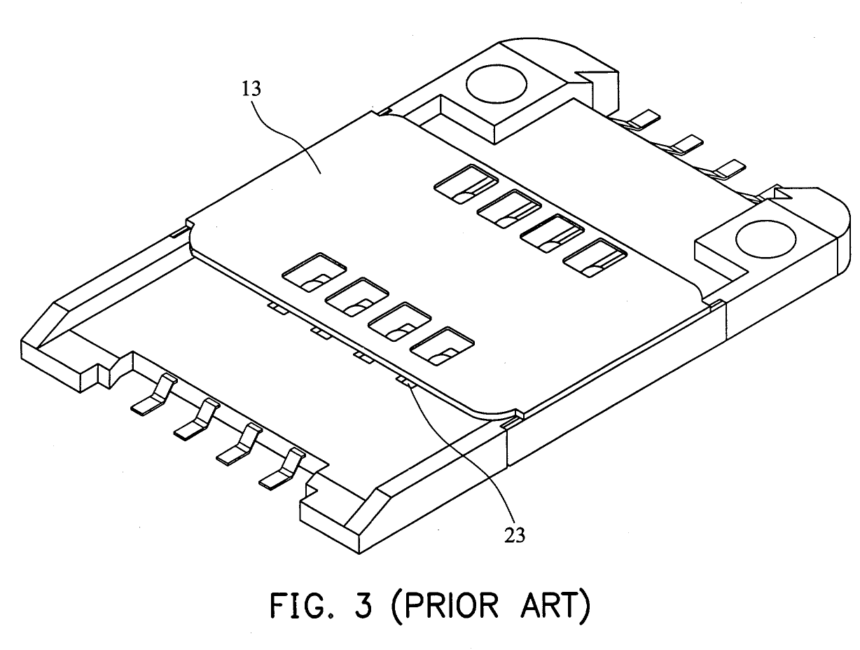

### DETAILED DESCRIPTION OF THE INVENTION

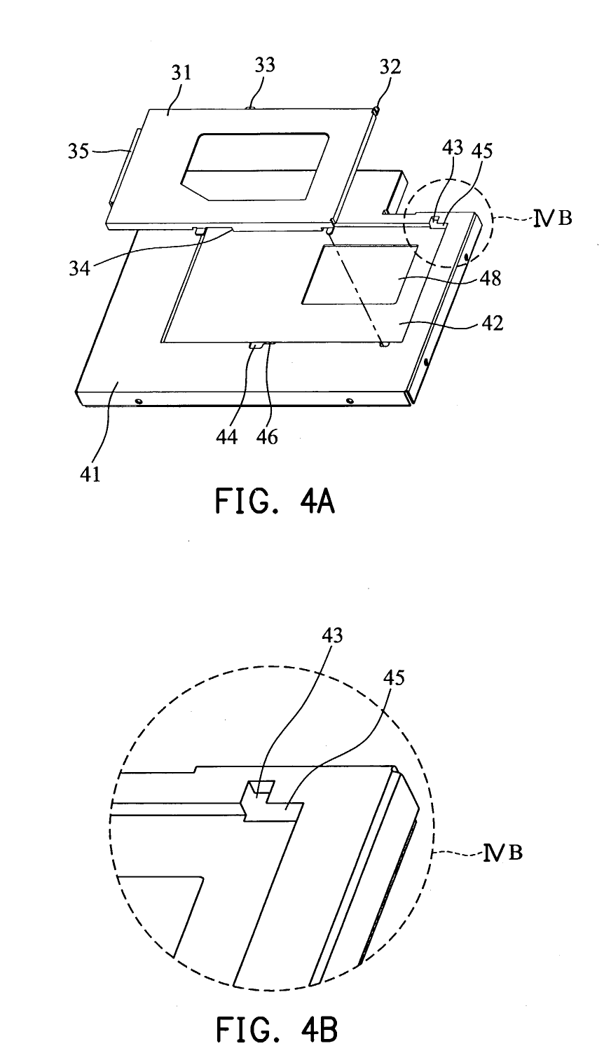

FIG. 4A is a schematic view of the apparatus of the present invention. A first plate 31 and a second plate 41 are made of electromagnetic interference shielding material. The first plate 31 and the second plate 41 are the main fixture elements in the present invention. The first plate 31 includes a pair of shafts 32 and tabs 33 and defines a pair of parallel grooves 34 for receiving the SIM card. The first plate 31 further includes a flange 35 and defines an opening 36 thereon, wherein the flange 35 is formed at the edge of the first plate 31 to ease engagement thereof.

The second plate 41 includes a depressed portion 42 to contain the first plate 31 and defines a through hole 48. The depressed portion 42 defines a pair of first holes 43, a pair of first channels 45, a pair of second holes 44 and a pair of second channels 46, wherein the pair of first channels 45 connect the pair of first holes 43, the pair of second channels 46 connect the pair of second holes 44, the pair of shafts 32 of the first plate 31 are slidably disposed in the pair of first channels 45, and the pair of tabs 33 are slidably disposed in the pair of second channels 46. The through hole 48 is utilized to connect the SIM card and a connector (not shown).

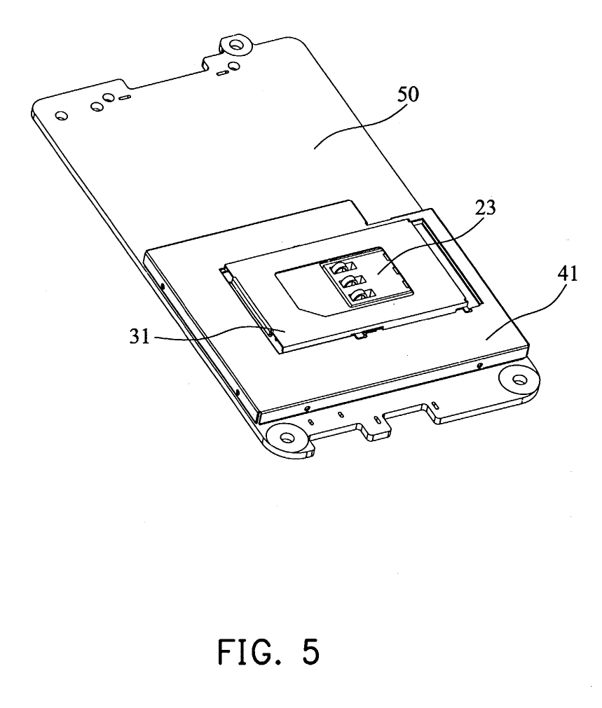

FIG. 5 shows the apparatus of the present invention disposed on the printed circuit board. The apparatus having the first plate 31 and the second plate 41 is disposed on a printed circuit board 50 in the case of a cell phone. The position on the printed circuit board of the apparatus in the present invention corresponds to the connector 23.

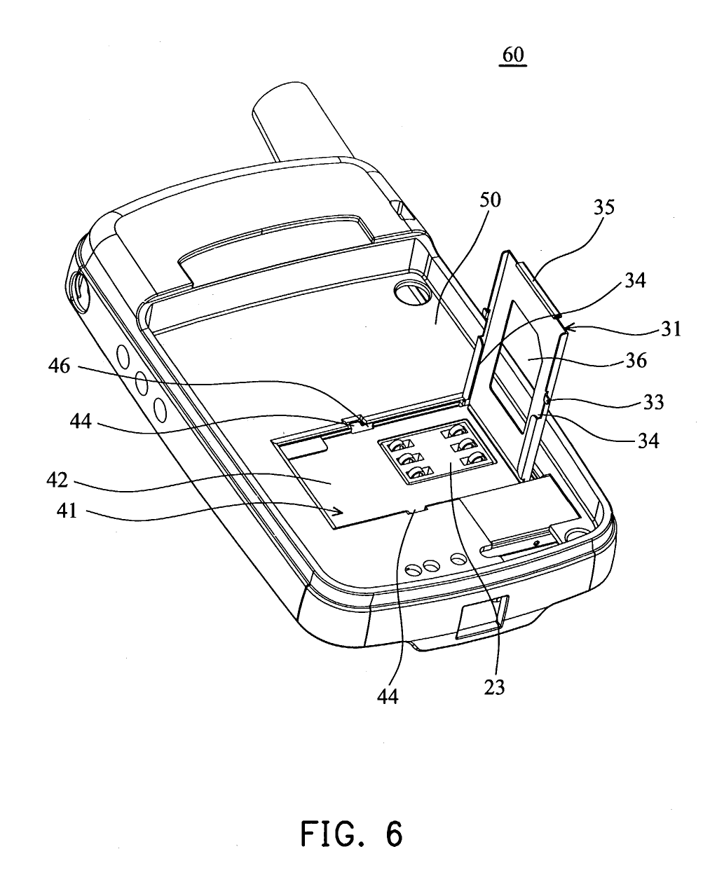

FIG. 6 shows the second plate 41 and the printed circuit board 50 embedded in a case 60 of a cell phone and the depressed portion 42 exposed in the case 60. In addition, the first holes 43, the first channels 45 and the second channel 46 are covered by the case 60. The first plate 31 is slidably connected to the second plate 41 so that the first plate 31 is slidable between a first position and a second position. Furthermore, the first plate 31 is rotatable with respect to the second plate 41 in the first position, and is engaged with the second plate 41 in the second position.

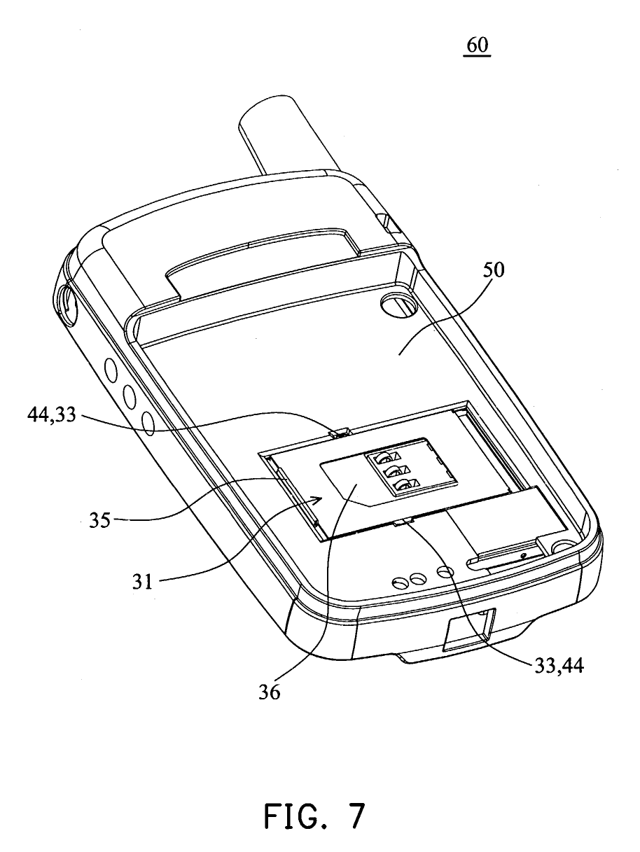

As shown in FIG. 7, the grooves of the first plate 31 receive a SIM card (not shown) and the first plate 31 is rotated to cover the second plates 41 in the first position, wherein the tabs 33 are disposed in the second holes 44.

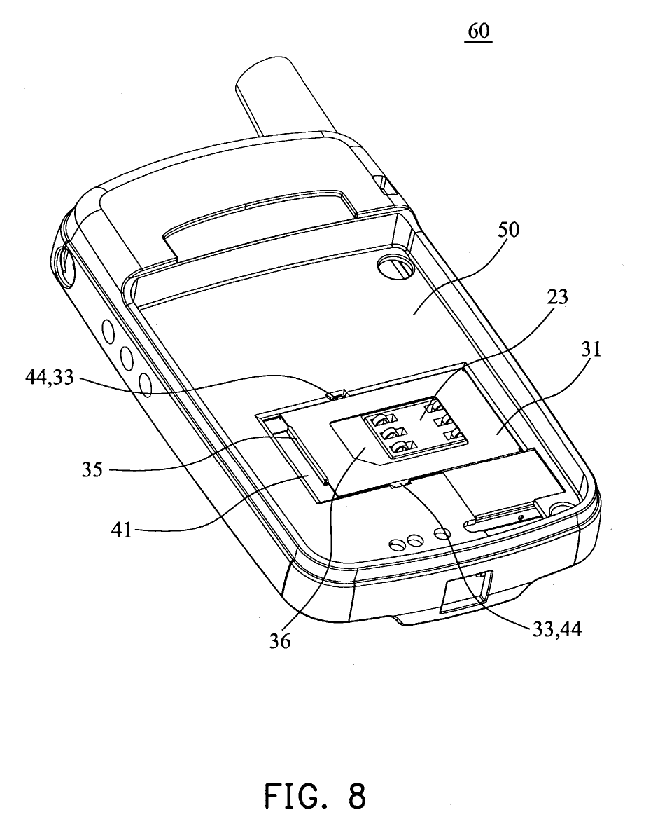

As shown in FIG. 8, the first plate 31 moves to the second position by engagement of the flange 35, wherein the shafts 32 and the tabs 33 slide in the first channels(not shown) and the second channels(not shown) respectively. Furthermore, the spring-type connector 23 also assists in fixing the SIM card between the first and second plates. The spring-type connector 23 biases the SIM card (not shown) against the second plate and subsequently solidly contacts the shafts 32 and tabs 33 with the edges of channels so that friction fixes the first plate 31 in the second position. In addition, the SIM card can be replaced by reversing the steps described above.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An apparatus for seating a Subscriber Identification Module (SIM) card, comprising:
a first plate including a pair of shafts and defining a pair of parallel grooves for receiving the SIM card; and
a second plate including a depressed portion to contain the first plate wherein the depressed portion defines a pair of holes and a pair of channels connecting the pair of holes, and the pair of shafts of the first plate are slidably disposed in the pair of channels.

2. The apparatus as claimed in claim 1, wherein the depressed portion further defines a through hole apart from the pair of holes and the pair of channels.

3. The apparatus as claimed in claim 1, wherein the first plate further includes a flange formed at an edge of the first plate.

4. The apparatus as claimed in claim 1, wherein the first plate is made of electro-magnetic interference shielding material.

5. The apparatus as claimed in claim 1, wherein the second plate is made of electromagnetic interference shielding material.

6. An apparatus for seating a SIM card, wherein the apparatus is embedded in a case of a cell phone, comprising:
a first plate including a pair of shafts and tabs and defining a pair of parallel grooves for receiving the SIM card; and
a second plate including a depressed portion to contain the first plate wherein the depressed portion defines a pair of first holes, a pair of first channels, a pair of second holes and a pair of second channels, the pair of first channels connecting the pair of first holes, the pair of second channels connecting the pair of second holes, the pair of shafts of the first plate slidably disposed in the pair of first channels, and the pair of tabs slidably disposed in the pair of second channels.

7. The apparatus as claimed in claim 6, wherein the depressed portion further defines a through hole apart from the pair of first and second holes and the pair of first and second channels.

8. The apparatus as claimed in claim 6, wherein the first plate further includes a flange formed at an edge of the first plate.

9. The apparatus as claimed in claim 6, wherein the first plate is made of electro-magnetic interference shielding material.

10. The apparatus as claimed in claim 6, wherein the second plate is made of electro-magnetic interference shielding material.

11. An apparatus for seating a SIM card, comprising:
a depressed member;
a planar fixture slidably connected to the depressed member so that the planar fixture moves between a first position and a second position, wherein the planar fixture is rotatable with respect to the depressed member in the first position, and is biased against the depressed member in the second position.

12. The apparatus as claimed in claim 11, wherein the planar fixture includes a pair of shafts, the depressed member defines a pair of channels seating the pair of shafts so that the pair of shafts move in the pair of channels.

13. The apparatus as claimed in claim 11, further comprising:
a connector; and
a case housing the depressed member, the planar fixture, and the connector, wherein the connector biases the planar fixture against the depressed member.
